(19) United States
(12) Patent Application Publication
(10) Pub. No.: US 2010/0176401 A1
(43) Pub. Date: Jul. 15, 2010

(54) X-RAY DETECTOR AND MANUFACTURING METHOD OF THE SAME

(76) Inventors: JAE-BOK LEE, Seoul (KR); Young-Bae Jung, Hwaseong-si (KR)

Correspondence Address: F. CHAU & ASSOCIATES, LLC, 130 WOODBURY ROAD, WOODBURY, NY, 11797, US

(21) Appl. No.: 12/683,262

(22) Filed: Jan. 6, 2010

(30) Foreign Application Priority Data
Jan. 9, 2009 (KR) 10-2009-0002011

(51) Int. Cl. H01L 31/119; H01L 31/18; H01L 29/786; H01L 21/336

(52) U.S. Cl. 257/59; 438/96; 257/72; 438/97; 438/158; 257/E21.414; 257/E31.091; 257/E29.288

(57) ABSTRACT

An X-ray detector includes a gate wire formed on a substrate, the gate wire including a gate line, a gate electrode, and a gate pad, a gate insulating layer formed on the gate wire, a data wire formed on the gate insulating layer, the data wire including a data line intersecting the gate line, a source electrode, a drain electrode, and a data pad, a lower storage electrode formed on the gate insulating layer, the lower storage electrode comprising an opaque conductor material, and an upper storage electrode formed on the lower storage electrode, the upper storage electrode connected to the source electrode.

### CROSS-REFERENCE TO RELATED APPLICATION

This application claims priority from Korean Patent Application No. 10-2009-0002011 filed on Jan. 9, 2009, the disclosure of which is incorporated herein by reference in its entirety.

### BACKGROUND OF THE INVENTION

1. Technical Field

The present disclosure relates to an X-ray detector and a method of manufacturing the same, and more particularly, to a direct-type X-ray detector and a method of manufacturing the same.

2. Discussion of the Related Art

An analog X-ray detector includes an X-ray sensitive film. To obtain an X-ray image, the X-ray sensitive film needs to be developed. A digital X-ray detector includes a thin film transistor (TFT) as a switching element. The digital x-ray detector can diagnose a phase of an object in real time. As such, an X-ray image for an X-ray diagnosis can be obtained in real time.

The digital X-ray detector is classified into a direct-type and an indirect-type according to a detecting method. In the indirect-type digital X-ray detector, X-rays are converted into visible light by a scintillator, and the converted visible light is then converted into electric charges by a photoelectric conversion device such as a photodiode. In the direct X-ray detector, an image is displayed by detecting electric charges generated in a photoconductive layer such as an amorphous selenium (“a-Se”) layer in response to X-ray radiation transmitted through an object.

### SUMMARY OF THE INVENTION

According to an exemplary embodiment of the present invention, there is provided an X-ray detector including a gate wire formed on a substrate and including a gate line, a gate electrode, and a gate pad, a gate insulating layer formed on the gate wire, a data wire formed on the gate insulating layer and including a data line intersecting the gate line, a source electrode and a drain electrode, and a data pad, a lower storage electrode formed on the gate insulating layer using an opaque conductor material, and an upper storage electrode formed on the lower storage electrode and connected to the source electrode.

According to an exemplary embodiment of the present invention, there is provided an X-ray detector including a gate wire formed on a substrate and including a gate line, a gate electrode, and a gate pad, a gate insulating layer formed on the gate wire, a data wire formed on the gate insulating layer and including a data line intersecting the gate line, a source electrode and a drain electrode, and a data pad, a lower storage electrode formed on the gate insulating layer using the same material with the data wire, and an upper storage electrode formed on the lower storage electrode using a transparent conductor material and connected to the source electrode.

According to an exemplary embodiment of the present invention, there is provided a manufacturing method of an X-ray detector, the method including forming a gate wire on a substrate, the gate wire including a gate line, a gate electrode, and a gate pad, forming a semiconductor layer on the gate electrode, forming a data wire and a lower storage electrode on the substrate, the data wire including a data line intersecting the gate line, a source electrode and a drain electrode, and a data pad, forming a source contact hole exposing the source electrode, and forming an upper storage electrode on the lower storage electrode, the upper storage electrode connected to the source electrode through the source contact hole.

### BRIEF DESCRIPTION OF THE DRAWINGS

Exemplary embodiments of the present invention can be understood in more detail from the following descriptions taken in conjunction with the accompanying drawings in which:

FIG. 1 is a layout view of an X-ray detector according to an exemplary embodiment of the present invention;

FIG. 2 is a cross-sectional view taken along the line II-II′ of FIG. 1;

FIG. 3 is a circuit diagram showing a pixel constituting an X-ray detector according to an exemplary embodiment of the present invention;

FIGS. 4a and 4b illustrate exemplary arrangements of an lower storage insulating layer according to an exemplary embodiment of the present invention; and

FIGS. 5a through 9b illustrate a method of manufacturing an X-ray detector according to an exemplary embodiment of the present invention.

### DETAILED DESCRIPTION OF EXEMPLARY EMBODIMENTS

The present invention will now be described more fully with reference to the accompanying drawings, in which exemplary embodiments of the invention are shown. The invention may, however, be embodied in many different forms and should not be construed as being limited to the embodiments set forth herein.

It will be understood that when an element is referred to as being “connected to” or “coupled to” another element or layer, it can be directly connected or coupled to the other element or layer or intervening elements or layers may be present.

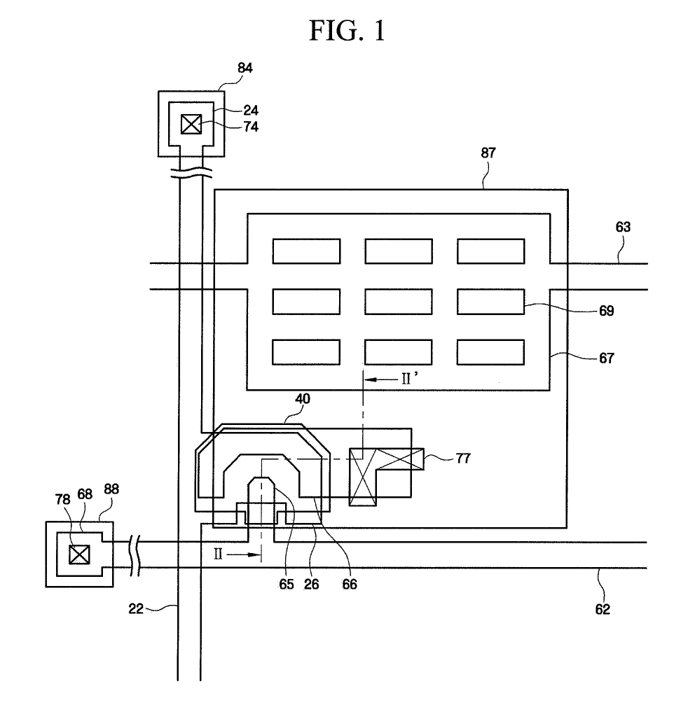

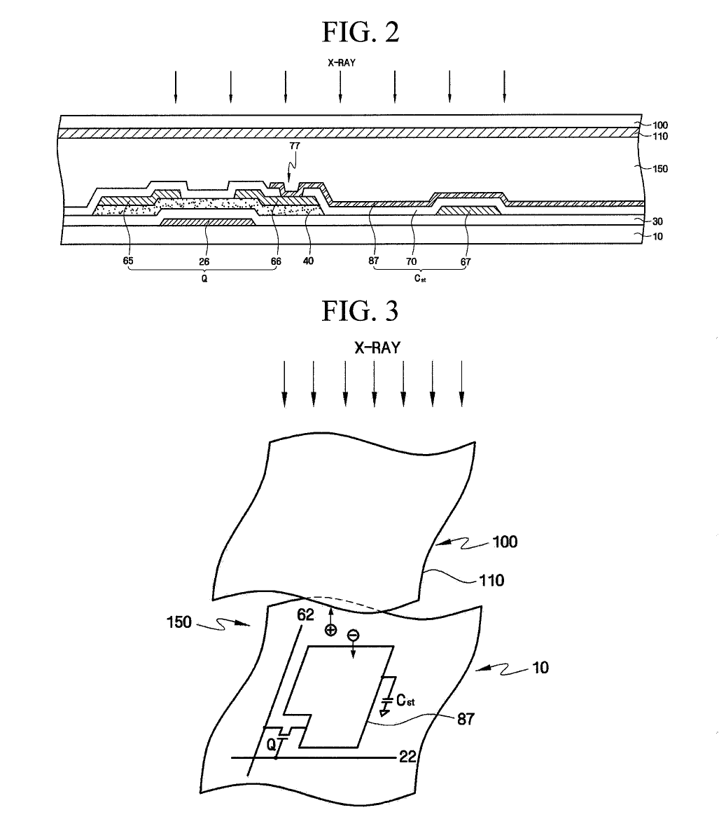

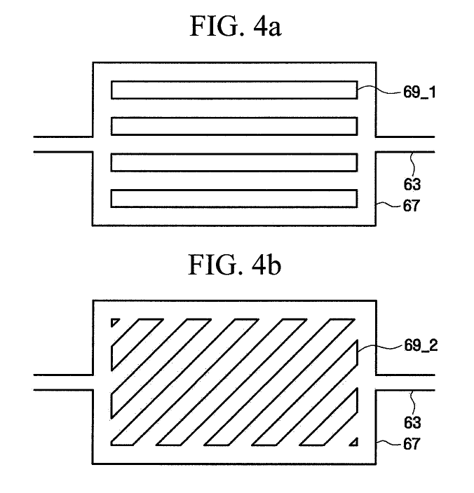

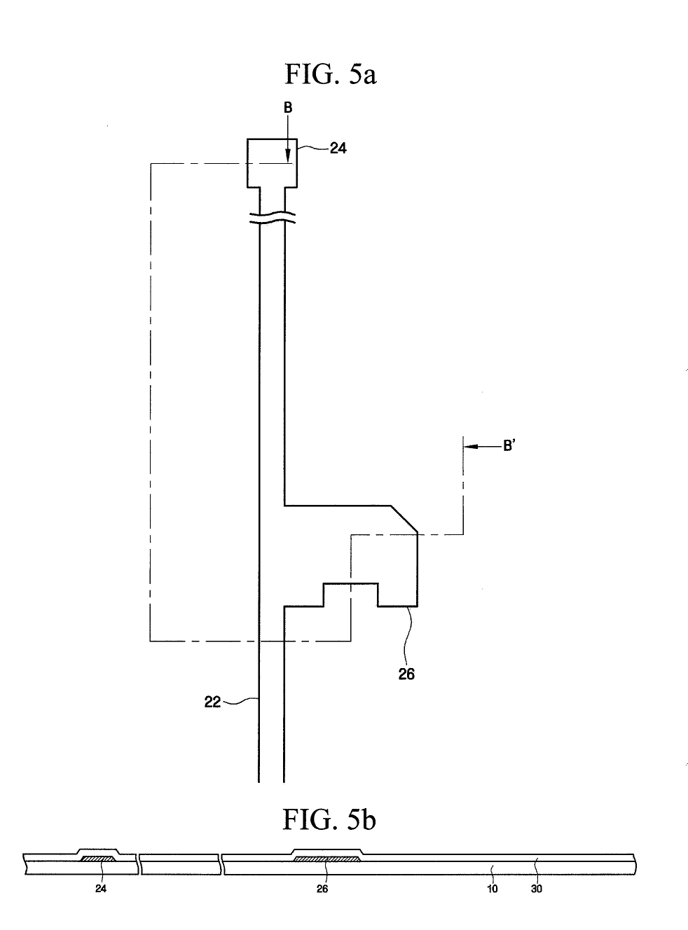

An X-ray detector according to an exemplary embodiment of the present invention is described with reference to FIGS. 1 through 4. FIG. 1 is a layout view of an X-ray detector according to an exemplary embodiment of the present invention. FIG. 2 is a cross-sectional view taken along the line II-II′ of FIG. 1. FIG. 3 is a circuit diagram showing a pixel constituting an X-ray detector according to an exemplary embodiment of the present invention. FIGS. 4a and 4b illustrate an arrangement of a lower storage insulating layer according to an exemplary embodiment of the present invention.

Referring to FIGS. 1 through 3, a plurality of gate wires of transmitting gate signals are formed on a first substrate 10. The first substrate 10 may comprise, for example, glass, such as soda lime glass or borosilicate glass, or plastic.

The gate wire 22, 24, 26 includes a gate line 22 formed in a longitudinal direction, a gate line end portion (e.g., a gate pad) 24 formed at an end of the gate line 22, and a gate electrode 26 of a TFT Q. The gate electrode 26 is connected to the gate line 22 and can protrude from the gate line 22. The gate line end portion 24 receives a gate signal from the outside and transmits the received gate signal to the gate line 22.

The gate wire 22, 24, 26 may comprise, for example, Al containing metal such as Al and Al alloy, Ag containing metal such as Ag and Ag alloy, Cu containing metal such as Cu and Cu alloy, Mo containing metal such as Mo and Mo alloy, Cr, Ti or Ta. In an exemplary embodiment, the gate wire 22, 24, 26 may have a multi-layered structure including two conductive films having different physical characteristics. One of the two films may comprise a low resistivity metal including, for example, Al containing metal, Ag containing metal, and Cu containing metal for reducing signal delay or voltage drop in the gate wire 22, 24, 26. The other film may comprise material such as, for example, a Mo containing metal, Cr, Ti or Ta, which have good physical, chemical, and electrical contact characteristics with other materials such as, for example, indium tin oxide (ITO) or indium zinc oxide (IZO). In an exemplary embodiment, the two films may include a lower Cr film and an upper Al (alloy) film and a lower Al (alloy) film and an upper Mo (alloy) film. In an exemplary embodiment, the gate wire 22, 24, 26 may comprise various metals or conductors.

A gate insulating layer 30 may comprise, for example, silicon nitride (SiNx) and can be formed on the gate wire 22, 24, 26.

A semiconductor layer 40 may comprise amorphous silicon hydride or polycrystalline silicon on the gate electrode 26 and the gate insulating layer 30. The semiconductor layer 40 may be formed in various shapes such as an island shape or a line shape. In an exemplary embodiment, the semiconductor layer 40 is formed in the island shape.

In an exemplary embodiment, an ohmic contact layer comprising silicide or n+ amorphous silicon hydride in which an n-type impurity is highly doped may be formed on the semiconductor layer 40.

The data wire 62, 65, 66, 68 and a storage wire 63, 67 are formed on the gate insulating layer 30.

The data wire 62, 65, 66, 68 is formed in a transverse direction, and includes a data line 62 intersecting the gate line 22, a drain electrode 65, a data pad 68 and a source electrode 66. The source electrode 66 is separated from the drain electrode 65 and is positioned opposite to the drain electrode 65 with respect to the gate electrode 26 or a channel portion of the TFT Q. The source electrode 66 is formed on the ohmic contact layers. The drain electrode 65 is disposed on the ohmic contact layers and protrudes from the data line 62. The data pad 68 is connected to an end of the data line 62 and transmits an image signal including, for example, electric charges collected from a photoconductive layer 150 to a read circuit.

At least a portion of the drain electrode 65 overlaps the semiconductor layer 40. The drain electrode 65 is positioned opposite to the source electrode 66 with respect to the gate electrode 26 and at least a portion thereof overlaps the semiconductor layer 40. In an exemplary embodiment, the ohmic contact layers are interposed between the overlying drain electrode 65 and the source electrode 66 to reduce the contact resistance between the drain electrode 65 and the source electrode 66.

The storage electrode wire 63, 67 may include a storage electrode line 63 protruding substantially in parallel with the data line 62 and a lower storage electrode 67. The lower storage line 67 is connected to the storage electrode line 63 and having a width greater than that of the storage electrode line 63. In an exemplary embodiment, a ground voltage may be applied to the lower storage electrode 67. The lower storage electrode 67 may overlap the upper storage electrode 87 as shown, for example, in FIG. 3, to form a storage capacitor Cst for improving storage retention capacity.

The data wire 62, 65, 66, 68 and the storage electrode wire 63, 67 may comprise refractory metal such as, for example, Cr, a metal containing Mo, Ta, or Ti. In an exemplary embodiment, the data wire 62, 65, 66, 68 and the storage electrode wire 63, 67 may have a multi-layered structure including a lower film comprising a lower refractory metal film and a low-resistivity upper film. Examples of the multi-layered structure include a double-layered structure having a lower Cr film and an upper Al (alloy) film, a double-layered structure having a lower Mo (alloy) film and an upper Al (alloy) film, and a triple-layered structure having a lower Mo film, an intermediate Al film, and an upper Mo film.

When the lower storage electrode 67 comprises an opaque conductor material, the lower storage electrode 67 may include a slit pattern 69. For example, the lower storage electrode 67 includes the slit pattern 69 to ensure a predetermined transmission ratio of an electroluminescence (EL) backlight irradiated downward with respect to the first substrate 10. In an exemplary embodiment, the EL backlight may be provided from an EL portion disposed below the first substrate 10 to reset a charge trap formed in the photoconductive layer 150 using X-ray radiation.

The slit pattern 69 may include a plurality of multiple slits in an array, as shown, for example, in FIG. 1. The slits may have a variety of shapes, including, for example, rectangular, polygonal, circular, and oval shapes. In alternative embodiments, the slit pattern 69 may be implemented in various manners. For example, the slit pattern 69 may be shaped of straight lines 69_1 or slant lines 69_2, as shown, for example, in FIGS. 4A and 4B.

To ensure the predetermined transmission ratio of the EL backlight, the overall area of the slit pattern 69 can be about 43% or more of the area of the lower storage electrode 67.

When the lower storage electrode 67 comprises an opaque conductor material, the area of the lower storage electrode 67 may be smaller than that of the upper storage electrode 87 for ensuring the predetermined transmission ratio of the EL backlight according to an exemplary embodiment of the present invention.

A passivation layer 70 is formed on the semiconductor layer 40, the data wire 62, 65, 66, 68, and the storage electrode wire (63, 67). For example, the passivation layer 70 may comprise an inorganic material such as silicon nitride or silicon oxide, a photosensitive organic material having a good flatness characteristic, or a low dielectric insulating material such as a-Si:C:O and a-Si:O:F formed by plasma enhanced chemical vapor deposition (PECVD). In an exemplary embodiment, when the passivation layer 70 comprises an organic material, the passivation layer 70 may be formed as a double layer comprising a lower inorganic layer and an upper organic layer to prevent the organic material of the passivation layer 70 from contacting an exposed portion of the semiconductor layer 40. As such, the characteristics of the passivation layer 70 as an organic layer can be preserved.

The upper storage electrode 87 is formed on the passivation layer 70. The upper storage electrode 87 is electrically connected to the source electrode 66 through a source contact hole 77 exposing the source electrode 66, and collects electric charges formed in the photoconductive layer 150 using X-ray radiation. In an exemplary embodiment, the upper storage electrode 87 is formed at an intersection area of the gate line 22 and the data line 62, and may correspond to a pixel of a displayed image detected by an X-ray detector.

The upper storage electrode 87, the passivation layer 70 and the lower storage electrode 67 constitute a storage capacitor Cst to collect and retain electric charges formed in the photoconductive layer 150. To sufficiently retain the electric charges formed in the photoconductive layer 150, capacitance of the storage capacitor Cst can be in a range of about 0.1 pF to about 0.4 pF. In an exemplary embodiment, the capacitance of the storage capacitor Cst may be adjusted to be in the range stated above in consideration of a thickness of a material forming the passivation layer 70 and an overlapping area of the upper storage electrode 87 and the lower storage electrode 67. For example, when the area of the lower storage electrode 67 is substantially small that the overlapping area of the upper storage electrode 87 and the lower storage electrode 67 becomes small, the capacitance of the storage capacitor Cst may be adjusted by forming the passivation layer 70 using a highly dielectric index or by reducing the thickness of the passivation layer 70, thereby ensuring a predetermined transmission ratio of the EL backlight.

A gate pad electrode 84 is formed on the passivation layer 70. The gate pad electrode 84 is electrically connected to the gate pad 24 through a first contact hole 74 exposing the gate pad 24. In an exemplary embodiment, the gate pad electrode 84 receives a gate signal from a gate driver. A data pad electrode 88 is formed on the passivation layer 70. The data pad electrode 88 is electrically connected to the data pad 68 through a second contact hole 78 exposing the data pad 68. The data pad electrode 88 transmits an image signal to a read circuit.

In an exemplary embodiment, the gate driver and the read circuit may be mounted on a flexible printed circuit film to be connected to the gate pad electrode 84 and the data pad electrode 88 in the form of a tape carrier package. In an exemplary embodiment, the gate driver and the read circuit may be formed on the first substrate 10 in the form of an integrated circuit (IC) comprising at least one thin film transistor to then be attached to the gate pad electrode 84 and the data pad electrode 88.

The upper storage electrode 87, the gate pad electrode 84 and the data pad electrode 88 may comprise a transparent conductor material such as ITO or IZO.

The photoconductive layer 150, which supplies electric charges in response to X-ray radiation, is formed on the passivation layer 70 and the upper storage electrode 87. For example, the photoconductive layer 150 generates electric charges in proportion to an intensity of the X-ray radiation and supplies the electric charges to the upper storage electrode 87. The photoconductive layer 150 may comprise, for example, amorphous selenium (a-Se), mercury (II) iodide (HgI₂), lead oxide (PbO), cadmium telluride (CdTe), cadmium selenide (CdSe), cadmium sulfide (CdS), or thallium bromide (TlBr). The photoconductive layer 150 can be amorphous selenium (a-Se).

A second substrate 100 having the upper electrode 110 is formed on the photoconductive layer 150. A predetermined voltage is applied to the upper electrode 110, and among the electric charges generated from the photoconductive layer 150, second charges are supplied to the upper storage electrode 87 while first charges are separately collected. When a positive voltage, for example, is applied to the upper electrode 110, electrons generated in the photoconductive layer 150 are collected in the upper electrode 110, while holes are collected in the upper storage electrode 87. When a negative voltage is applied to the upper electrode 110, holes generated in the photoconductive layer 150 are collected in the upper electrode 110 while electric charges are collected in the upper storage electrode 87.

When electric charges are generated in a photoconductive layer in response to X-ray radiation, the generated electric charges are collected and stored in the upper storage electrode 87. When the electric charges are transmitted to the data wire 62, 65, 66, 68 according to the gate signal applied to the gate wire 22, 24, 26, a read circuit reads the transmitted electric charges and outputs image signals corresponding to the electric charges.

A method of manufacturing the X-ray detector according to an exemplary embodiment of the present invention is described with reference to FIGS. 5a through 9b. FIGS. 5a through 9b illustrate intermediate structures of various processing steps of a method of manufacturing an X-ray detector according to an exemplary embodiment of the present invention, in which ‘b’ drawings are cross-sectional views taken along the lines B-B′ of ‘a’ drawings, respectively.

Referring first to FIGS. 5a and 5b, the gate wire 22, 24, 26, including the gate line 22, the gate electrode 26, and the gate pad 24, is formed on the first substrate 10.

The first substrate 10 may comprise, for example, glass, such as soda lime glass or borosilicate glass, or plastic.

In an exemplary embodiment, the forming of the gate wire 22, 24, 26 may include forming a gate wiring conductive film on the first substrate 10, and patterning the gate wiring conductive film using a first mask.

Forming the gate wiring conductive film may be performed by, for example, sputtering, or evaporation deposition. In an exemplary embodiment, the gate wiring conductive film may be fowled by depositing a conductive film comprising Al containing metal such as Al and Al alloy, Ag containing metal such as Ag and Ag alloy, Cu containing metal such as Cu and Cu alloy, Mo containing metal such as Mo and Mo alloy, Cr, Ti or Ta, by sputtering, or evaporation deposition.

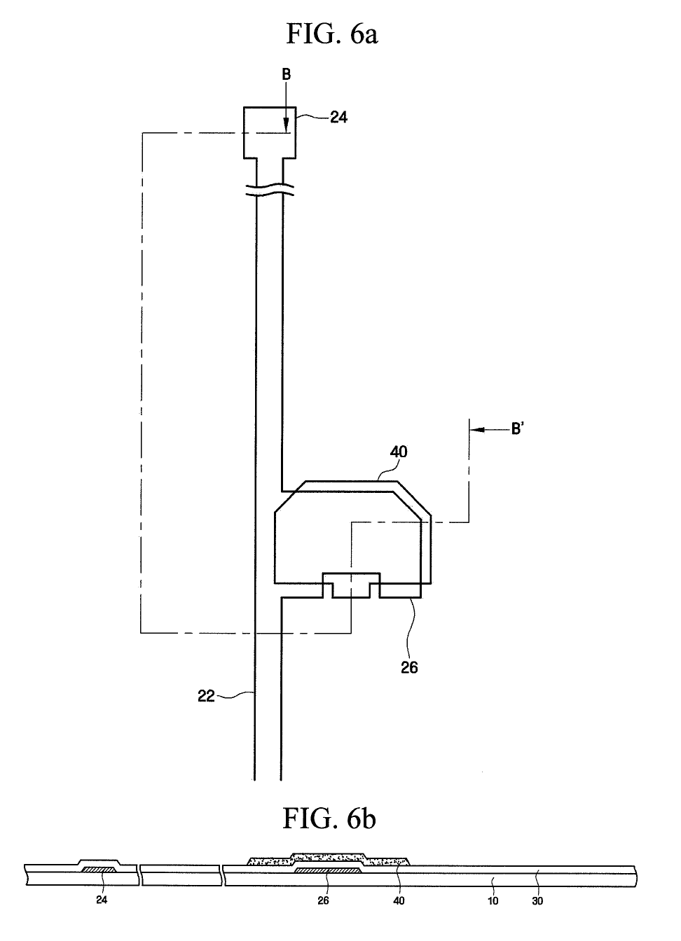

Referring to FIGS. 6a and 6b, the gate insulating layer 30 comprising silicon nitride (SiNx) is formed on the first substrate 10, and the semiconductor layer 40 is then formed on the gate electrode 26.

In an exemplary embodiment, forming the semiconductor layer 40 may include forming a pre-semiconductor layer comprising amorphous silicon hydride or polycrystalline silicon on a substrate, and forming the semiconductor layer 40 of, for example, an island shape, using a second mask. The pre-semiconductor layer can be formed on the gate insulating layer 30. An ohmic contact layer may be formed on the semiconductor layer 40.

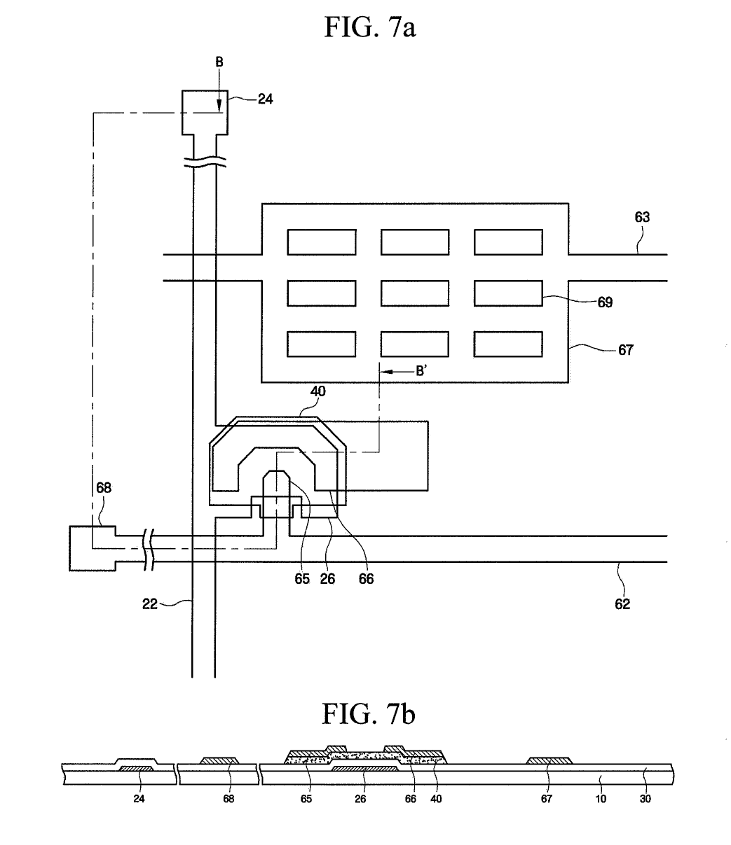

Referring to FIGS. 7a and 7b, the data wire 62, 65, 66, 68 and the storage wire 63, 67 are formed on the first substrate 10. In an exemplary embodiment, the data wire 62, 65, 66, 68 includes the data line 62, the drain electrode 65, the source electrode 66 and the data pad 68. The storage electrode wire 63, 67 includes the storage electrode line 63 and the lower storage electrode 67.

A first conductive film is formed on the first substrate 10, and the first conductive film is then patterned using a third mask, thereby forming the data wire 62, 65, 66, 68 and the storage electrode wire 63, 67. The first conductive film may comprise, for example, refractory metal such as Cr, a metal containing Mo, Ta, or Ti. The first conductive film may have a multi-layered structure including a lower film comprising a lower refractory metal film and a low-resistivity upper film. Examples of the multi-layered structure include a double-layered structure having a lower Cr film and an upper Al (alloy) film, a double-layered structure having a lower Mo (alloy) film and an upper Al (alloy) film, and a triple-layered structure having a lower Mo film, an intermediate Al film, and an upper Mo film.

In exemplary embodiments of the present invention, since the lower storage electrode 67 comprises the same material as the data wire 62, 65, 66, 68, a separate mask for forming the lower storage electrode 67 can be omitted. When the lower storage electrode 67 comprises a transparent conductor material such as ITO, additional steps for preventing indium oxides in ITO from being reduced by hydrogen radicals in subsequent processing steps may be omitted. Accordingly, the manufacturing method of the X-ray detector according to an exemplary embodiment of the present invention can be simplified, which can reduce the manufacturing cost of the X-ray detector.

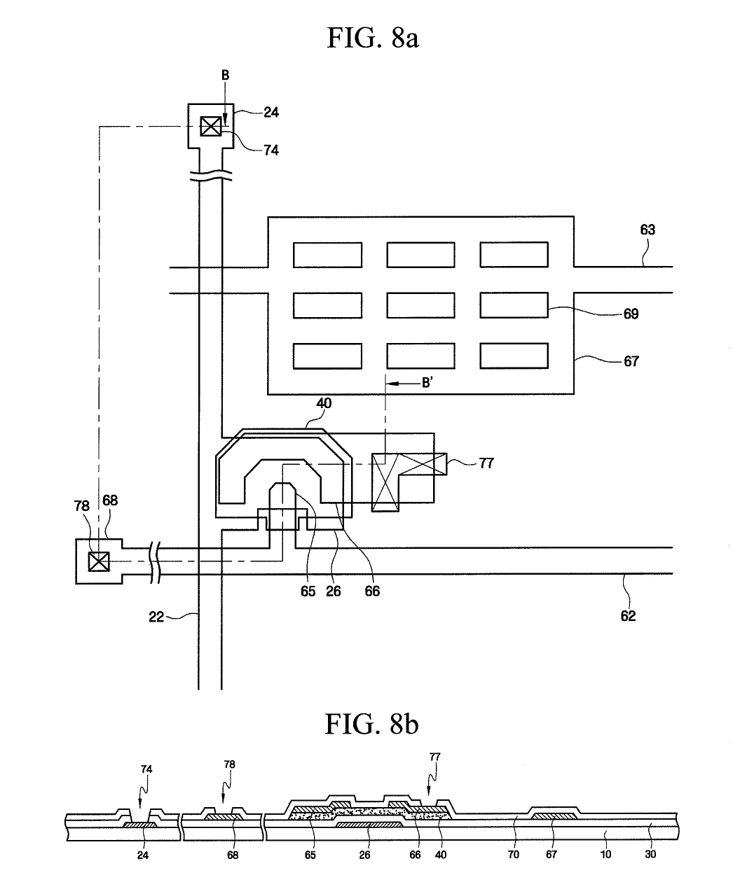

Referring to FIGS. 8a and 8b, the passivation (protective) layer 70 is formed on the first substrate 10, and the source contact hole 77 and the first and second contact holes 78 are formed on the passivation layer 70.

The passivation layer 70 may comprise a single layer or multiple layers comprising an inorganic material such as silicon nitride or silicon oxide, a photosensitive organic material having a good flatness characteristic, or a low dielectric insulating material such as a-Si:C:O and a-Si:O:F formed by plasma enhanced chemical vapor deposition (PECVD).

The passivation layer 70 is patterned using a fourth mask to form the source contact hole 77 exposing the source electrode 66, and the first and second contact holes 78 exposing the gate pad 24 and the data pad 68, respectively.

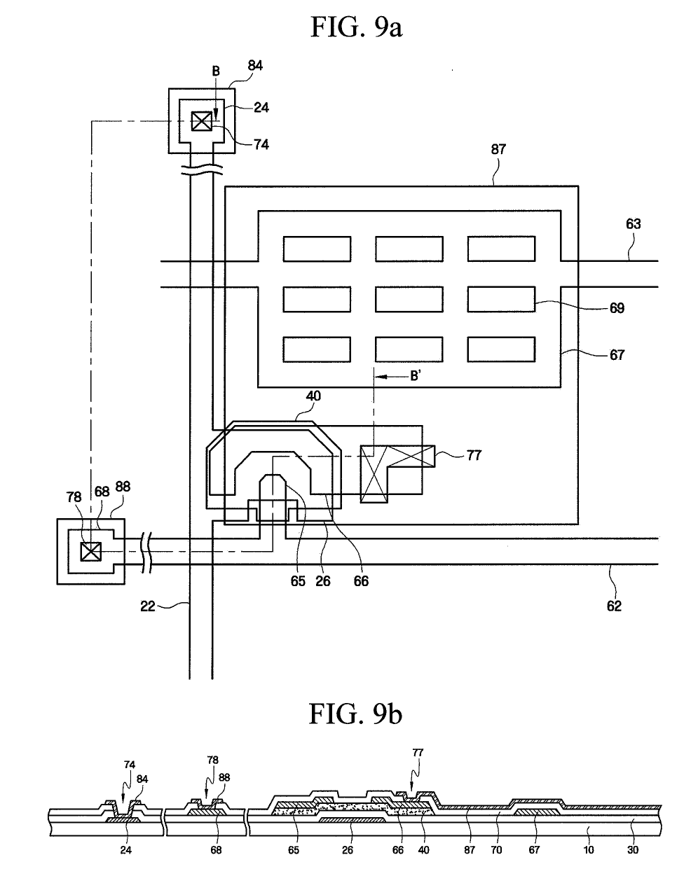

Referring to FIGS. 9a and 9b, the upper storage electrode 87, the gate pad electrode 84 and the data pad electrode 88 are formed on the passivation layer 70.

In an exemplary embodiment, a second conductive film is formed on the first substrate 10, and the second conductive film is then patterned using a fifth pattern, thereby forming the upper storage electrode 87, the gate pad electrode 84 and the data pad electrode 88. In an exemplary embodiment, the second conductive film may comprise a transparent conductive material such as ITO or IZO, or a conductive polymer material.

In exemplary embodiments of the present invention, since the gate pad electrode 84 and the data pad electrode 88 comprise the same materials as the upper storage electrode 87, the gate pad electrode 84 and the data pad electrode 88 can be formed without using a separate mask, thereby simplifying the manufacturing method of the X-ray detector according to an exemplary embodiment of the present invention.

According to exemplary embodiments of the present invention, the gate pad electrode 84 and the data pad electrode 88 comprise a transparent conductive material such as ITO or IZO, or a conductive polymer material.

In an exemplary embodiment, a photoconductive layer is formed on the upper storage electrode 87. The photoconductive layer may comprise amorphous selenium (a-Se), mercury (II) iodide (HgI₂), lead oxide (PbO), cadmium telluride (CdTe), cadmium selenide (CdSe), cadmium sulfide (CdS), or thallium bromide (TlBr). In an exemplary embodiment, a second substrate having an upper substrate is formed on the photoconductive layer.

Although the exemplary embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. An X-ray detector comprising:
a gate wire formed on a substrate, the gate wire including a gate line, a gate electrode, and a gate pad;
a gate insulating layer formed on the gate wire;
a data wire formed on the gate insulating layer, the data wire including a data line intersecting the gate line, a source electrode, a drain electrode, and a data pad;
a lower storage electrode formed on the gate insulating layer, the lower storage electrode comprising an opaque conductor material; and
an upper storage electrode formed on the lower storage electrode, the upper storage electrode connected to the source electrode.

2. The X-ray detector of claim 1, further comprising a photoconductive layer formed on the upper storage electrode, the photoconductive layer supplying electric charges in response to X-ray radiation.

3. The X-ray detector of claim 1, wherein the upper storage electrode comprises a transparent conductor material.

4. The X-ray detector of claim 1, wherein the lower storage electrode and the data wire comprise the same material.

5. The X-ray detector of claim 1, wherein the lower storage electrode includes a slit pattern.

6. The X-ray detector of claim 5, wherein the slit pattern includes a plurality of multiple slits in an array.

7. The X-ray detector of claim 5, wherein an overall area of the slit pattern is about 43% or more of an area of the lower storage electrode.

8. The X-ray detector of claim 1, further comprising:
a gate pad electrode connected to the gate pad through a first contact hole; and
a data pad electrode connected to the data pad through a second contact hole,
wherein the gate pad electrode and the data pad electrode comprise the same material with the upper storage electrode.

9. The X-ray detector of claim 1, further comprising a passivation layer formed on the lower storage electrode, wherein a capacitance of a storage capacitor including the passivation layer, the lower storage electrode and the upper storage electrode is in a range of about 0.1 pF to about 0.4 pF.

10. An X-ray detector comprising:
a gate wire formed on a substrate, the gate wire including a gate line, a gate electrode, and a gate pad;
a gate insulating layer formed on the gate wire;
a data wire formed on the gate insulating layer, the data wire including a data line intersecting the gate line, a source electrode, a drain electrode, and a data pad;
an lower storage electrode formed on the gate insulating layer, the lower storage electrode comprising the same material with the data wire; and
an upper storage electrode formed on the lower storage electrode, the upper storage electrode comprising a transparent conductor material and connected to the source electrode.

11. The X-ray detector of claim 10, wherein the lower storage electrode includes a slit pattern.

12. The X-ray detector of claim 10, further comprising:
a gate pad electrode connected to the gate pad through a first contact hole; and
a data pad electrode connected to the data pad through a second contact hole,
wherein the gate pad electrode and the data pad electrode comprise the same material with the upper storage electrode.

13. A method of manufacturing an X-ray detector comprising:
forming a gate wire on a substrate, the gate wire including a gate line, a gate electrode, and a gate pad;
forming a gate insulating layer on the gate electrode;
forming a data wire and a lower storage electrode on the gate insulating layer, the data wire including a data line intersecting the gate line, a source electrode, a drain electrode, and a data pad;
forming a source contact hole exposing the source electrode; and
forming an upper storage electrode on the lower storage electrode, the upper storage electrode connected to the source electrode through the source contact hole.

14. The method of claim 13, wherein forming the data wire and the lower storage electrode comprises forming an opaque conductive film on the substrate, and patterning the opaque conductive film.

15. The method of claim 13, wherein the lower storage electrode includes a slit pattern.

16. The method of claim 15, wherein the slit pattern includes a plurality of multiple slits in an array.

17. The method of claim 15, wherein an overall area of the slit pattern is about 43% or more of an area of the lower storage electrode.

18. The method of claim 13, further comprising forming a first contact hole and a second contact hole through which the gate pad and the data pad are exposed, respectively, wherein forming the first and second contact holes is performed at the same time with forming the source contact hole.

19. The method of claim 18, further comprising forming a gate pad electrode connected the gate pad through the first contact hole, and a data pad electrode connected to the data pad through the second contact hole at the same time with forming the upper storage electrode,
wherein forming the upper storage electrode, the gate pad electrode and the data pad electrode includes depositing a transparent conductive film on the substrate, and patterning the transparent conductive film.

20. The method of claim 13, further comprising a photoconductive layer supplying electric charges to the substrate in response to X-ray radiation.
